(19) United States
(12) Patent Application Publication
(10) Pub. No.: US 2026/0201226 A1
(43) Pub. Date: Jul. 16, 2026

(54) SURFACE TREATMENT METHOD OF CERIUM OXIDE, CERIUM OXIDE, AND USE THEREOF

(71) Applicant: ANJI MICROELECTRONICS TECHNOLOGY (SHANGHAI) CO., LTD., Pudong New Area, Shanghai (CN)

(72) Inventors: Xingping WANG, Shanghai (CN); Pengyu XU, Shanghai (CN); Zhan CHEN, Shanghai (CN); Yinbin CHEN, Shanghai (CN); Shoutian LI, Shanghai (CN)

(21) Appl. No.: 19/138,042

(22) PCT Filed: Dec. 12, 2023
(86) PCT No.: PCT/CN2023/138027

§ 371 Date: Jun. 11, 2025

(30) Foreign Application Priority Data
Dec. 13, 2022 (CN) 202211595667.1

(51) Int. Cl. C09K 3/14; C09G 1/02

(52) U.S. Cl. CPC C09K 3/1436; C09G 1/02

(57) ABSTRACT

The present invention provides a surface treatment method of cerium oxide, comprising S1: adding a first additive to deionized water, stirring uniformly, adding cerium oxide particles, and then transferring the solution to an ultrasonic tank, ultrasonically dispersing it for 10-90 min until the cerium oxide particles are dispersed uniformly; S2: adding a second additive to the above dispersed solution, stirring uniformly, transferring it to an ultrasonic tank, ultrasonically dispersing it for 30-180 min, until the cerium oxide particles are evenly dispersed. By adding cation-containing polymer molecules, polymerized ion pairs are achieved through charge attraction, realizing double-layer coating on the surface of cerium oxide. The double-coated cerium oxide particles have a high polishing rate and leveling efficiency, much higher than the traditional alkaline ILD polishing solution with silicon oxide as the abrasive particle.

### TECHNICAL FIELD

The present invention relates to the field of chemical mechanical polishing, to a surface treatment method of cerium oxide, a cerium oxide and its application.

### BACKGROUND

In the existing technology, the preparation method of cerium oxide includes sol-gel method and calcination method. Cerium oxide made by sol-gel method is generally the surface has not undergone charge treatment, with a positive charge; cerium oxide made by calcination method usually use anion to do surface treatment, the surface of the positive charge is reversed into a negative charge, the anion is usually obtained from the molecules containing phosphoric acid or phosphite or polyacrylic acid. After inversion of the surface to a negative charge, the surface coating can only reach a certain thickness. In order to increase the thickness of the surface coating layer, polymer molecules with anionic and cationic ions can be used to increase the thickness of the cerium oxide surface coating by polymerizing ion pairs through charge attraction, allowing the surface coating layer to become multiple layers of molecules with different compositions. Increase the thickness of the cerium oxide surface coating layer, the theory makes the particles to reduce the mechanical collision force on the surface of the wafer, reduce the mechanical force due to the scratch.

The flattening efficiency of cerium oxide polishing solutions is closely related to the surface properties of cerium oxide particles, and in existing technology, the regulation of cerium oxide properties is often achieved by changing the preparation process of cerium oxide particles. We found that cerium oxide particles can be modified more efficiently by surface treatment engineering techniques, and satisfactory treatment results can be obtained.

Proper modification of cerium oxide particles can greatly improve the chemical-mechanical leveling efficiency of cerium oxide polishing solutions, which in turn reduces the amount of polishing solution used in the polishing process, provides productivity, and reduces the cost of the polishing process.

### DESCRIPTION

In order to solve the above technical problems, the present invention provides a surface treatment method of cerium oxide, comprising:
S1: adding a first additive to deionized water, stirring uniformly, adding cerium oxide particles, and then transferring the solution to an ultrasonic tank, ultrasonically dispersing for 10-90 min until the cerium oxide particles are uniformly dispersed, and forming a first dispersion solution;
S2: adding a second additive to the first dispersion solution, mixing uniformly and then transferring the solution to an ultrasonic tank, ultrasonically dispersing for 30-180 min, until the cerium oxide particles are uniformly dispersed.

Preferably, the ultrasonic frequency is 20-400 KHZ.

Preferably, the first additive is a Carboxylic acid-based, sulfonic acid-based polymers; the second additive is a cation-containing polymer.

Preferably, the first additive is selected from one or more of polyaspartic acid, polymethacrylic acid, Poly(sodium 4-styrenesulfonate), Poly (4-styrenesulfonic acid-co-maleic acid).

Preferably, the mass percentage content of the first additive relative to the cerium oxide is 0.01 wt %-10 wt %.

Preferably, the second additive is a polyquaternary ammonium salt.

Preferably, the mass percentage content of the second additive relative to the cerium oxide is 0.01 wt %-10 wt %.

Another aspect of the present invention provides a cerium oxide, it is treated using a surface treatment method for cerium oxide as described above.

Another aspect of the present invention provides an application of the cerium oxide for chemical mechanical polishing.

In the technical solution of the present invention, a second charge reversal to a positive charge is achieved by realizing a second capping of the cerium oxide surface by adding cation-containing polymer molecules, which reach a polymeric ion pair by charge attraction. The second coated cerium oxide particles have a high polishing rate and leveling efficiency, much higher than the conventional alkaline ILD polishing solution with silicon oxide as the abrasive particle.

### EMBODIMENTS

The advantages of the present invention are further described below in connection with specific embodiments.

All content percentages in the present invention refer to mass percentage content.

Embodiment 1: Using polyaspartic acid as a first additive.

The surface treatment method in this embodiment comprises:
S1: adding polyaspartic acid to deionized water, stirring for 5 min, then adding cerium oxide, stirring for 30 min, transferring the solution to an ultrasonic tank, ultrasonically dispersing for 60 min, and adjusting the pH of the dispersion to 4.8.

The cerium oxide used in the comparative embodiments 1A-1G were cerium oxide with an effective content of 30%, and the light scattering measurement yielded a particle size of 160 nm; the cerium oxide used in the comparative embodiment 1H was cerium oxide with an effective content of 30%, and the light scattering measurement yielded a particle size of 185 nm. After the treatment of the above step S1, the zeta potential on the surface of the cerium oxide of the respective comparative embodiment and embodiments was measured, and the particle size of the cerium oxide was observed, particle size was measured, and the stability of the cerium oxide colloid was observed.

The concentration of the first additive in the comparative embodiments 1A-1H and the results of the above measurements are shown in Table 1.

TABLE 1
Concentration of each component in comparative embodiments1A-1H and stability test results

| | comparative | comparative | comparative | comparative | comparative | comparative | comparative | comparative |
|---|---|---|---|---|---|---|---|---|
| | embodiment | embodiment | embodiment | embodiment | embodiment | embodiment | embodiment | embodiment |
| | 1A | 1B | 1C | 1D | 1E | 1F | 1G | 1H |
| polyaspartic acid | 0.03% | 0.04% | 0.05% | 0.06% | 0.07% | 0.08% | 0.10% | 0.07% |
| cerium oxide | 10% | 10% | 10% | 10% | 10% | 10% | 10% | 10% |
| Polyquaternium | — | — | — | | | | | — |
| Zeta potential (mv) | inapplicable | inapplicable | inapplicable | −7 | −30 | <−30 | <−30 | −33 |
| Cerium oxide | inapplicable | inapplicable | inapplicable | grow up | 160 | 160 | 160 | 185 |
| particle size (nm) | | | | | | | | |
| stability | precipitates | precipitates | precipitates | <3 weeks | >3 weeks | >3 weeks | >3 weeks | >3 weeks |

According to the data in Table 1, it can be seen that when 0.03%, 0.04%, and 0.05% polyaspartic acid were added for charge reversal in the comparative embodiments 1A-1C, respectively, precipitation appeared; this indicates that the amount of the first additive added was not enough to produce effective charge repulsion to stabilize the colloid. When 0.06% polyaspartic acid (comparative embodiment 1D) was added, the surface potential (zeta) of the particles could reach −7 mV. at this time, the charge on the surface of the particles began to reverse, but the repulsion was not strong enough. The particles started to grow after 3 weeks and showed colloidal instability. When 0.07% poly(aspartic acid) is added (comparative embodiment 1E), the zeta potential becomes −30 mV, and there is enough repulsion between the particles, the particle size is 160 nm, and there is no growth, and it can be stabilized for more than 3 weeks. When more polyaspartic acid is added, such as 0.08% and 0.1%, the zeta potential stays above below −30 mV and the particles can exist stably.

Embodiment 2: Based on the test results in embodiment 1, cerium oxide particles comparative embodiments 1E, 1G and 1H were selected for a second charge reversal. This is specified as follows:
S2: Adding a second additive to said dispersion and adjusting the pH of said dispersion until 4.8.

Embodiment 2A: 5.0 g of 2% polyquaternium-37 (PQ-37) was added to 895.0 g of deionized water, stirred for 5 minutes, 100.0 g of 10% of cerium oxide particles in Comparative embodiment 1G was added, stirred for 30 minutes, transferred to a 20 kHz ultrasonic bath, and ultrasonically dispersed for 120 minutes.

Embodiment 2B: 5.0 g of 2% polyquaternium-37 (PQ-37) was added to 895.0 g of deionized water, stirred for 5 minutes, 100.0 g of 10% of cerium oxide particles from Comparative embodiment 1E was added, stirred for 30 minutes, transferred to a 20 kHz ultrasound bath, and sonicated and dispersed for 120 minutes.

Embodiment 2C: 5.0 g of 2% polyquaternium-2 (PQ-2) was added to 895.0 g of deionized water, stirred for 5 minutes, 100.0 g of 10% of cerium oxide particles from Comparative embodiment 1E was added, stirred for 30 minutes, transferred to a 20 kHz ultrasound bath, and sonicated and dispersed for 120 minutes.

Embodiment 2D: 5.0 g of 2% polyquaternium-37 (PQ-37) was added to 895.0 g of deionized water, stirred for 5 minutes, 100.0 g of 10% cerium oxide particles from Comparative embodiment 1H was added, stirred for 30 minutes, transferred to a 20 kHz ultrasound bath, and sonicated and dispersed for 120 minutes.

TABLE 2
Content and stability test results of each component in
embodiments2A-2D

| | embodiment | embodiment | embodiment | embodiment |
|---|---|---|---|---|
| | 2A | 2B | 2C | 2D |
| polyaspartic acid | 0.03% | 0.04% | 0.05% | 0.06% |
| cerium oxide | 1% | 1% | 1% | 1% |
| Polyquaternium | 0.01% | 0.01% | 0.01% | 0.01% |
| | PQ-37 | PQ-37 | PQ-2 | PQ-37 |
| Zeta potential | +35 | +30 | +25 | +21 |
| (mv) | | | | |
| Cerium oxide | 160 | 160 | 160 | 185 |
| particle size | | | | |
| (nm) | | | | |
| stability | >3 weeks | >3 weeks | >3 weeks | >3 weeks |

Based on the test results in Table 2, it can be seen that the surface potential (zeta) of the particles started to reverse after the second charge reversal had been performed, and that the cerium oxide abrasive particles were able to be preserved for more than 3 weeks with good stability. In order to further measure the polishing performance of the dispersion in embodiments 2A-2D, a Mirra polishing bench was used to perform polishing tests on TEOS blank wafers.

The corresponding polishing test conditions included: IC1010 polishing pad, Platten and Carrier speeds of 93 rpm and 87 rpm, respectively, pressures adjusted to 2 psi, 3 psi, and 4 psi, and a flow rate of the polishing solution of 150 mL/min. The TEOS film thickness was measured with a NanoSpec Film Thickness Measurement System (NanoSpec6100-300, Shanghai Nanospec Technology Corporation). Shanghai Nanospec Technology Corporation). Starting at 3 mm from the wafer edge, 49 points were measured at equal intervals along the diameter line. The polishing rate is the average of the 49 points.

In order to compare the TEOS polishing rates, the conventional ILD polishing solution (12.5% silicon oxide, pH 11) with fumed silica as the base of the abrasive particles was used as a comparative embodiment 2. The polishing rates are listed in Table 3.

TABLE 3
Polishing test results for embodiments 2A-2D and comparative
embodiment 2.

| | | Polishing rate at different | | | |
|---|---|---|---|---|---|
| | Abrasive | polishing pressures (A/min) | | | |
| samples | particles | 1.5 psi | 2 psi | 3 psi | 4 psi |
| embodiment 2A | 0.2% cerium oxide | 2539 | 3020 | 3945 | 4730 |
| embodiment 2B | 0.2% cerium oxide | 2342 | 2845 | 4090 | 4859 |
| embodiment 2C | 0.2% cerium oxide | 1280 | 1709 | 2561 | 3365 |
| embodiment 2D | 0.2% cerium oxide | 2795 | 3437 | 4562 | 5448 |
| comparative embodiment | 12.5% cerium | 1223 | 1595 | 2342 | 2921 |
| 2 (Alkaline silicon oxide | oxide | | | | |
| ILD polishing solution) | | | | | |

Based on the test data in Table 3, it can be seen that the use of a 0.2% cerium oxide grinding solution in the present invention has a higher TEOS polishing rate than the conventional 12.5% silicon oxide as the particle ILD polishing solution. The cerium oxide particles after two charge reversals have excellent polishing properties.

Embodiment 3: Use of polymethacrylic acid as a first additive; use of polyquaternary ammonium salt as a second additive. Specifically as follows:

Comparative embodiment 3A: 10.0 g of 5% polymethacrylic acid (molecular weight ~5000) was added to 656.0 g of deionized water and stirred for 5 minutes, then, 333.3 g of 30% cerium oxide (particle size of 160 nm as measured by light scattering) was added, and after stirring for 30 minutes, the solution was transferred to an ultrasonic bath at 20 kHz and ultrasonically dispersed for 60 minutes. The pH of the dispersion was adjusted to 4.8

Comparative embodiment 3B: 10.0 g of 5% polymethacrylic acid (molecular weight ~5000) was added to 656.7 g of deionized water and stirred for 5 minutes, then 333.3 g of 30% cerium oxide (particle size 185 nm as measured by light scattering) was added, and stirred for 30 minutes, then the solution was transferred to a 20 kHz ultrasonic bath, and ultrasonically dispersed for 60 minutes. The pH of the dispersion was adjusted to 4.8

Embodiment 3A: 2.5 g of 2% polyquaternium-37 (PQ-37) was added to 977.5 g of deionized water, stirred for 5 minutes, 20.0 g of 10% of cerium oxide particles from comparative embodiment 3A was added, stirred for 30 minutes, and then the solution was transferred to a 20 kHz ultrasonic bath and sonicated and dispersed for 120 minutes. The pH of the dispersion was adjusted to 4.8

Embodiment 3B: 2.5 g of 2% polyquaternium-37 (PQ-37) was added to 977.5 g of deionized water, stirred for 5 minutes, 20.0 g of 10% of cerium oxide particles from comparative embodiment 3B was added, stirred for 30 minutes, transferred to a 20 kHz ultrasonic bath, and sonicated and dispersed for 120 minutes. The pH of the dispersion was adjusted to 4.8

The content and test results of each additive used in embodiments 3A, 3B and in comparative embodiments 3A and 3B are shown in Table 4.

TABLE 4
Content and stabilization test results of each component used
in embodiments 3A, 3B and the comparative embodiments 3A and 3B

| | | Cerium | | | | | |
|---|---|---|---|---|---|---|---|
| | | oxide | | Polyquaternary | Zeta | | |
| | Reverse | particle | Polymethacrylic | ammonium | potential | particle | Colloidal |
| samples | sequence | size (nm) | acid (%) | salt type | (mv) | size (nm) | Stability |
| Comparative | the first time | 160 | 0.005% | — | −28 mV | 160 | >3 weeks |
| Embodiment 3A | | | | | | | |
| Comparative | the first time | 185 | 0.005% | — | −43 mV | 185 | >3 weeks |
| Embodiment 3B | | | | | | | |
| Embodiment 3A | the second time | 160 | 0.005% | PQ-37 | +45 mV | 160 | >3 weeks |
| Embodiment 3B | the second time | 185 | 0.005% | PQ-37 | +35 mV | 185 | >3 weeks |

Based on the data in Table 4, it can be seen that when using polymethacrylic acid as the first additive, the same technical effect of reversing the surface charge of the particles can be achieved and, moreover, the stability of the cerium oxide colloid can be maintained to facilitate the subsequent second charge reversal. The polishing performance of the cerium oxide dispersion obtained in embodiments 3A and 3B was further tested. Specific tests were performed as described in embodiment 2. The test results are shown in Table 5.

| | | Polishing rate at different | | | |
|---|---|---|---|---|---|
| | | polishing pressures (A/min) | | | |
| | Abrasive particles | 1.5 psi | 2 psi | 3 psi | 4 psi |
| Embodiment 3A | 0.2% cerium oxide | 1949 | 2632 | 3832 | 4217 |
| Embodiment 3B | 0.2% cerium oxide | 2100 | 3035 | 3983 | 5140 |
| Comparative | 12.5% cerium oxide | 1223 | 1595 | 2342 | 2921 |
| Embodiment 2 | | | | | |

Comparison with comparative embodiment 2 shows that embodiment 3A and embodiment 3B containing 0.2% cerium oxide grinding solution have higher TEOS polishing rates than conventional ILD polishing solution with 12.5% silicon oxide as particles. The cerium oxide particles after two charge reversals had excellent polishing performance.

Embodiment 4: Use of a sulfonic acid containing polymer as a first additive and a polyquaternary ammonium salt as a second additive.

Comparative embodiment 4A: 5.60 g of 18% Poly(sodium 4-styrenesulfonate) was added to 661.1 g of deionized water and stirred for 5 minutes, then, 333.3 g of 30% cerium oxide (particle size of 170 nm as measured by light scattering) was added and stirred for 30 minutes, then the solution was transferred to a 20 kHz ultrasonic bath and dispersed by ultrasound for 60 minutes.

Comparative embodiment 4B: 20.0 g of 5% Poly(4-styrenesulfonic acid-co-maleic acid) was added to 646.7 g of deionized water and stirred for 5 minutes, then, 333.3 g of 30% cerium oxide (particle size 170 nm as measured by light scattering) was added, stirred for 30 minutes, and then, the solution was transferred to a 20 kHz ultrasonic bath and sonically dispersed for 60 minutes.

Embodiment 4A: 2.5 g of 2% polyquaternium-37 (PQ-37) was added to 977.5 g of deionized water, stirred for 5 minutes, 20.0 g of 10% of the cerium oxide particles in comparative embodiment 4A was added, stirred for 30 minutes, transferred to a 20 kHz ultrasonic bath, and sonicated and dispersed for 120 minutes.

Embodiment 4B: 2.5 g of 2% polyquaternium-37 (PQ-37) was added to 977.5 g of deionized water, stirred for 5 minutes, 20.0 g of 10% of the cerium oxide particles from comparative embodiment 4B was added, stirred for 30 minutes, transferred to a 20 kHz ultrasonic bath, and sonicated and dispersed for 120 minutes.

The zeta potentials and particle sizes of cerium oxide particles before and after surface treatment are listed in Table 6.

TABLE 6
Content and stability test results of each component in embodiments 4A, 4B and comparative embodiments 4A and 4B

| | | Cerium | | | | | |
|---|---|---|---|---|---|---|---|
| | | oxide | | Polyquaternary | | | |
| | Reverse | particle | Anionic polymer | ammonium | zeta | Particle | Colloidal |
| samples | sequence | size (nm) | (% ) | salt type | potential | size (nm) | Stability |
| Comparative | the first time | 170 | 0.01% Poly (sodium | — | −49 mV | 170 | >3 weeks |
| Embodiment 4A | | | 4-styrenesulfonate) | | | | |
| Comparative | the first time | 170 | Poly (4-styrenesulfonic | — | −28 mV | 170 | >3 weeks |
| Embodiment 4B | | | acid-co-maleic acid) | | | | |
| Embodiment 4A | the econd time | 170 | 0.01% Poly (sodium | PQ-37 | +42 mV | 170 | >3 weeks |
| | | | 4-styrenesulfonate) | | | | |
| Embodiment 4B | the econd time | 170 | Poly (4-styrenesulfonic | PQ-37 | +40 mV | 170 | >3 weeks |
| | | | acid-co-maleic acid) | | | | |

Based on the data in Table 6, it can be seen that when using a sulfonic acid-based polymer containing a sulfonic acid-based polymer as the first additive, the same technical effect of reversing the surface charge of the particles can be achieved and, moreover, the stability of the cerium oxide colloid can be maintained to facilitate the subsequent second charge reversal. The polishing performance of the cerium oxide dispersion obtained in embodiments 4A and 4B was further tested. Specific tests were performed as described in embodiment 2. The test results are shown in Table 7.

TABLE 7
Polishing test results of embodiment 4A, embodiment 4B and
particles

| | | Polishing rate at different | | | |
|---|---|---|---|---|---|
| | Abrasive | polishing pressures (A/min) | | | |
| | particles | 1.5 psi | 2 psi | 3 psi | 4 psi |
| embodiment 4A | 0.2% cerium oxide | 2149 | 2805 | 3579 | 4407 |
| embodiment 4B | 0.2% cerium oxide | 2422 | 3198 | 4469 | 5440 |
| comparative | 12.5% cerium | 1223 | 1595 | 2342 | 2921 |
| embodiment 2 (Alkaline | oxide | | | | |
| silicon oxide ILD | | | | | |
| polishing solution) | | | | | |

Comparison with comparative embodiment 2 shows that embodiment 4A and embodiment 4B containing 0.2% cerium oxide polishing solution have higher TEOS polishing rates than the conventional ILD polishing solution with 12.5% silicon oxide as particles. The cerium oxide particles after two charge reversals have excellent polishing performance.

Based on the test results of the above contrasting ratios and embodiments, it can be seen that for the first coating of the cerium oxide particle surface, molecules containing carboxyl, amino acid, and sulfonate functional groups are selected for use, and the amount added is usually no more than 2% of the unit weight of the abrasive particles. For the second coating, cationic polymer molecules, such as polyquaternary ammonium salts, are added to achieve a second charge reversal to a positive charge by charge attraction and polymerization of ion pairs. Generally, the amount of polyquaternium salt does not exceed 3% of the unit weight of the abrasive particles.

Through the realization of the second coating on the surface of cerium oxide, the addition of cation-containing polymer molecules, through the charge attraction, to reach the polymerization of ion pairs, to achieve the second charge reversal, into a positive charge. The second coated cerium oxide particles have a high polishing rate and leveling efficiency, much higher than the traditional alkaline ILD polishing solution with silicon oxide as the abrasive particle.

Although the above specific embodiments of the present invention have been described in detail, they are only embodiments, and the present disclosure is limited to the embodiments described above. For those skilled in the art, any equivalent modification and substitution to the present invention is also covered in the present invention. Therefore, all these equivalent changes and modifications made without departing from the spirit and scope of the invention should be covered within the scope of the present invention.

1. A surface treatment method of cerium oxide, comprises:
S1: adding a first additive to deionized water, stirring uniformly, adding cerium oxide particles, and then transferring the solution to an ultrasonic tank, ultrasonically dispersing for 10-90 min until the cerium oxide particles are uniformly dispersed, and forming a first dispersion solution;
S2: adding a second additive to the first dispersion solution, stirring uniformly and then transferring the solution to an ultrasonic tank, ultrasonically dispersing for 30-180 min, until the cerium oxide particles are uniformly dispersed.

2. The surface treatment method for cerium oxide as claimed in claim 1, wherein, the first additive is a Carboxylic acid-based, sulfonic acid-based polymers; the second additive is a cation-containing polymer.

3. The surface treatment method for cerium oxide as claimed in claim 2, wherein, the first additive is selected from one or more of polyaspartic acid, polymethacrylic acid, Poly(sodium 4-styrenesulfonate), Poly(4-styrenesulfonic acid-co-maleic acid).

4. The method for surface treatment of cerium oxide as claimed in claim 2, wherein the mass percentage content of the first additive relative to the cerium oxide is 0.01 wt %-10 wt %.

5. The surface treatment method for cerium oxide as claimed in claim 2, wherein, the second additive is a polyquaternary ammonium salt.

6. The surface treatment method for cerium oxide as claimed in claim 2, wherein the mass percentage content of the second additive relative to the cerium oxide is 0.01 wt %-10 wt %.

7. A cerium oxide, treated using the surface treatment method for cerium oxide of claim 1.

8. An application of cerium oxide as claimed in claim 7 for chemical mechanical polishing.
